(19) United States
(12) Patent Application Publication
(10) Pub. No.: US 2012/0291850 A1
(43) Pub. Date: Nov. 22, 2012

(54) CONCENTRATING SOLAR BATTERY, CONCENTRATING SOLAR BATTERY MODULE, CONCENTRATING SOLAR BATTERY SYSTEM, METHOD FOR MANUFACTURING CONCENTRATING SOLAR BATTERY, AND METHOD FOR MANUFACTURING CONCENTRATING SOLAR BATTERY MODULE

(76) Inventor: Hiroyuki Juso, Osaka-shi (JP)

(21) Appl. No.: 13/519,784

(22) PCT Filed: Dec. 24, 2010
(86) PCT No.: PCT/JP2010/073343

§ 371 Date: Jun. 28, 2012

(30) Foreign Application Priority Data
Dec. 29, 2009 (JP) 2009-299015

(51) Int. Cl. H01L 31/052; H01L 31/18; H01L 31/0232

(52) U.S. Cl. 136/246; 136/259; 438/64; 438/66

(57) ABSTRACT

A concentrating solar battery in which concentrated sunlight is guided to a solar battery cell, the concentrating solar battery including: a substrate on which the solar battery cell is mounted; a light guide member disposed above the solar battery cell such that a lower surface thereof opposes the solar battery cell; and a support member that holds an upper portion of the light guide member in a hanging manner and is provided upright on the substrate, wherein the concentrating solar battery has a structure hermetically sealed by the substrate, the light guide member and the support member.

### TECHNICAL FIELD

The present invention relates to a concentrating solar battery module structure in which concentrated high-energy sunlight is directed to a solar battery cell.

### BACKGROUND ART

In recent years, with increasing awareness of environmental protection, demand is growing for the development of clean energy. In particular, solar power generation is gaining greater importance, and there is demand for low cost solar power generation systems to further promote their widespread use.

A concentrating solar power generation system is of a type that improves the output voltage of solar batteries by concentrating sunlight, and it is regarded as a high-potential system in which sunlight concentrated by an optical lens, a reflecting mirror or the like is directed to solar battery elements with a small area, whereby the power generated per unit area of solar battery elements is increased, the number of solar battery cells which are the most expensive component in the solar power generation system is reduced, and the entire cost of the system is reduced.

In a concentrating solar battery system, light concentrated by a primary optical lens is non-uniform with a high intensity at the center and a low intensity at the periphery. Accordingly, when the light concentrated by the primary optical lens is directed directly to the solar battery cells, the power generation efficiency decreases. To address this, a concentrating solar battery system as disclosed in Patent Document 1 has been proposed in which a secondary optical lens composed of a columnar light guide member is used, and light concentrated by a primary optical lens is blended by repeatedly undergoing total reflection at the inside face of the secondary optical lens while traveling through the secondary optical lens, so as to uniformalize the light intensity and spectral distribution.

FIG. 16 is a diagram showing a configuration of a concentrating solar battery system disclosed in Patent Document 1. The concentrating solar battery system includes a primary optical lens 42 for concentrating sunlight, a solar battery cell 80, a columnar secondary optical lens 70 that is for guiding sunlight concentrated by a primary optical lens 42 to the solar battery cell 80 and is provided in an upright manner directly above the solar battery cell 80 such that a lower surface of the columnar secondary optical lens 70 opposes the solar battery cell 80, and sealing resin 73 for covering the secondary optical lens 70 and the solar battery cell 80 opposing the lower surface. The secondary optical lens is composed of a glass member of polyhedron shape such as a truncated pyramidal or rectangular column shape, in consideration of durability, optical characteristics and the like.

### PRIOR ART DOCUMENT

### Patent Document

[Patent Document 1] JP 2009-187971A

### SUMMARY OF INVENTION

### Problems to be Solved by the Invention

The above configuration enables the sunlight concentrated by the primary optical lens to be efficiently guided to the solar battery cell by using the secondary optical lens. Also, the entire light-receiving face of the solar battery cell is covered with a resin sealant having good optical characteristics such as silicone resin, and it is therefore possible to protect the solar battery cell from damage, as well as preventing degradation of characteristics of the solar battery cell caused by moisture, salinity or acid adhering to the solar battery cell.

However, in the case where resin is used as the sealant used in the light-receiving face of the solar battery cell, because resin is generally susceptible to heat, likely to be deformed and easily degraded, if discoloration occurs in the resin due to irradiation with sunlight, there is a possibility that the light concentration efficiency and the amount of power generation by the solar battery cell might be reduced.

Also, the secondary optical lens for concentrating sunlight guides light by using total reflection at the inside face, but if there is dirt, dust and the like adhering to the surface, a problem arises in that the light is diffusely reflected at that portion and part of the light leaks to the outside. The energy equivalent to the leaked light results in power generation loss. Furthermore, glass is a brittle material, and thus there is another problem in that it is easily broken by an external impact.

The present invention has been conceived to solve the problems described above, and it is an object of the present invention to provide a concentrating solar battery module that prevents damage to and degradation of characteristics of a solar battery cell without sealing the light-receiving face of the solar battery cell with resin, and prevents dirt, dust and the like from adhering to a secondary optical lens so as to protect the solar battery cell from damage and degradation.

### Means for Solving the Problems

A concentrating solar battery according to the present invention is a concentrating solar battery in which concentrated sunlight is guided to a solar battery cell, the concentrating solar battery including: a substrate on which the solar battery cell is mounted; a light guide member disposed above the solar battery cell such that a lower surface thereof opposes the solar battery cell; and a support member that holds an upper portion of the light guide member in a hanging manner and is provided upright on the substrate, wherein the concentrating solar battery has a structure hermetically sealed by the substrate, the light guide member and the support member.

Also, in the concentrating solar battery according to the present invention, the support member may be configured using any one of Kovar, ceramic, soda-lime glass, borosilicate glass and stainless steel.

Also, in the concentrating solar battery according to the present invention, the light guide member may be configured using any one of quartz glass, Vycor glass, high alumina glass, soda-lime glass and borosilicate glass.

Also, in the concentrating solar battery according to the present invention, the concentrating solar battery may include a terminal for extracting current generated by the solar battery cell, and the terminal may have a structure that guides the current generated by the solar battery cell to an undersurface via a through hole formed in the substrate.

A concentrating solar battery module according to the present invention is a concentrating solar battery module in which a plurality of concentrating solar batteries are disposed on a plate, wherein a connecting portion that is connected to a solar battery cell and wiring for connecting solar battery cells are formed on the plate.

A concentrating solar battery system according to the present invention includes a concentrating solar battery module and a primary optical system that concentrates sunlight.

A method for manufacturing a concentrating solar battery according to the present invention is a method for manufacturing a concentrating solar battery in which concentrated sunlight is guided to a solar battery cell, the method including the steps of; holding an upper portion of a light guide member in a hanging manner by a support member, placing the support member upright on a substrate on which the solar battery cell is mounted, and hermetically sealing the concentrating solar battery.

A method for manufacturing a solar battery module according to the present invention is a method for manufacturing a solar battery module in which a plurality of concentrating solar batteries in which concentrated sunlight is guided to solar battery cells are disposed on a plate, the method including the steps of; holding an upper portion of a light guide member in a hanging manner by a support member, placing the support member upright on a substrate on which a solar battery cell is mounted, and hermetically sealing the concentrating solar battery; and connecting the concentrating solar battery to a connecting portion of the plate on which the connecting portion that is connected to the concentrating solar battery and wiring for connecting solar battery cells are formed.

The method for manufacturing a concentrating solar battery module according to the present invention may further include a step of applying resin in a space between the plate and the concentrating solar battery.

### Effects of the Invention

With the concentrating solar battery according to the present invention, it is possible to prevent degradation of characteristics of the solar battery cell by preventing moisture, salinity or acid in the air from adhering to the surface of the solar battery cell. Furthermore, resin is not used to seal the light-receiving face of the solar battery cell, and therefore the conventional problem of deformation, discoloration, overheating and the like caused by use of resin does not occur.

It is also possible to prevent dirt, dust and the like from adhering to the light guide member and affecting the light concentration efficiency, as well as preventing the light guide member from being damaged or broken by an external impact.

### BRIEF DESCRIPTION OF DRAWINGS

FIG. 1 is a schematic diagram of a concentrating solar battery system.

FIG. 2 is a cross-sectional view of a concentrating solar battery.

FIG. 3 is a cross-sectional view of a concentrating solar battery.

FIG. 4 shows plan views of a substrate.

FIG. 5 is a perspective view of a concentrating solar battery.

FIG. 6 is a perspective view of a light guide member.

FIG. 7 shows examples in which a light guide member is attached to a support member.

FIG. 8 shows examples in which a light guide member is attached to a support member.

FIG. 9 is a perspective view of a light guide member.

FIG. 10 is a perspective view of a light guide member.

FIG. 11 shows an example in which a light guide member is attached to a support member.

FIG. 12 is a plan view of a plate.

FIG. 13 is a cross-sectional view of the plate taken along the line A-A.

FIG. 14 is a cross-sectional view of a concentrating solar battery attached to the plate.

FIG. 15 is a cross-sectional view of the concentrating solar battery in which resin has been applied.

FIG. 16 is a diagram showing a configuration of a conventional concentrating solar battery system.

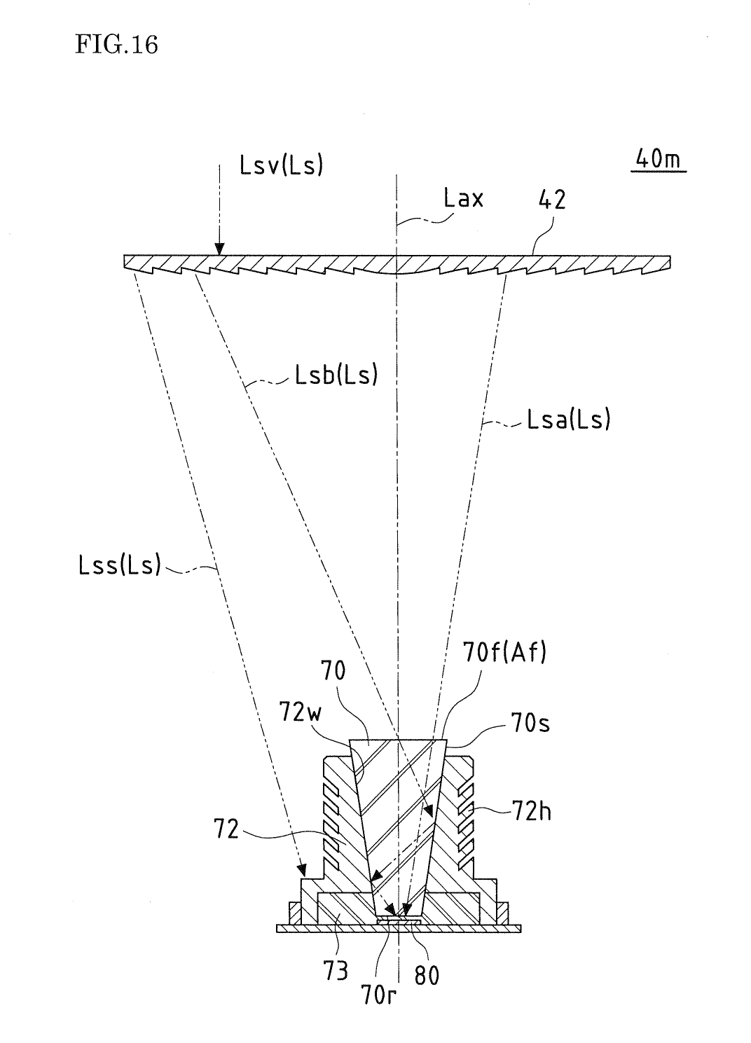

### MODES FOR CARRYING OUT THE INVENTION

Hereinafter, an embodiment of the present invention will be described. It should be noted that in the drawings of the present invention, the same reference numerals indicate the same or corresponding parts.

(Configuration of Concentrating Solar Battery)

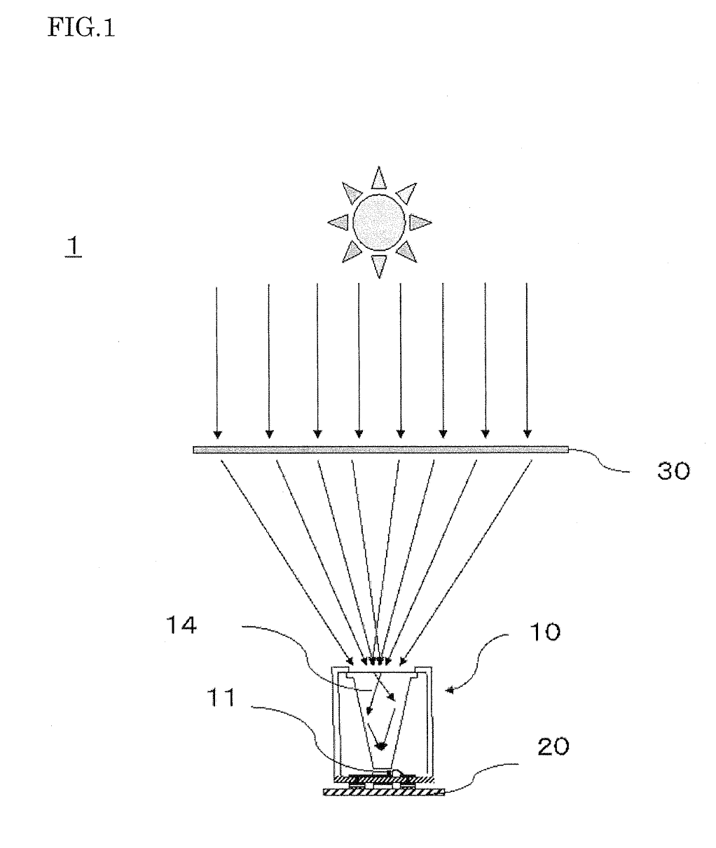

FIG. 1 is a schematic diagram of a concentrating solar battery system 1 according to an embodiment of the present invention. The concentrating solar battery system 1 is constituted by a primary optical lens 30 for concentrating sunlight, a concentrating solar battery 10 including a solar battery cell 11 and a light guide member 14 for guiding sunlight concentrated by the primary optical lens 30 to the solar battery cell 11, and a plate 20 in which wiring has been formed. A plurality of concentrating solar batteries 10 are disposed on the plate 20 to constitute a solar battery module in which the solar battery cells 11 are electrically connected. A plurality of solar battery modules as described above are disposed to constitute a solar battery array.

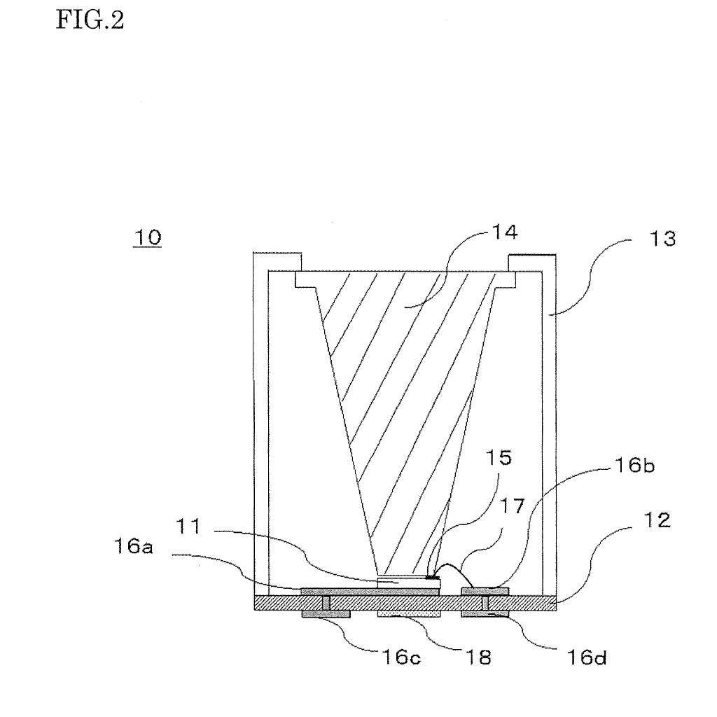

FIG. 2 is a cross-sectional view of a concentrating solar battery 10. The concentrating solar battery 10 includes a solar battery cell 11 that generates power by converting the applied sunlight concentrated by the light guide member 14 into electricity, and a substrate 12 on which the solar battery cell 11 is placed. The substrate 12 is surrounded by a support member 13. An upper portion of the support member 13 is formed to have an inverted L shape in cross section extending toward the inside. The light guide member 14 is held in place by a rim of the support member 13 such that the light guide member 14 opposes the solar battery cell 11, and is attached above the solar battery cell 11.

The solar battery cell 11 is an approximately 1 to 10 mm square chip processed from a wafer by forming a PN junction, electrodes and the like by a known semiconductor process using a semiconductor of any one or a combination of GaAs, Si, InGaP, GaN, AlInGaAs, AlGaAs, InGaAsN, Ge, CuInSe, CuInGaSe and CdTe.

The solar battery cell 11 includes a substrate electrode (not shown) on the back surface side of the chip (the plate 20 side) and a surface electrode 15 on the surface side of the chip. The current generated by the solar battery cell 11 is extracted from the substrate electrode and the surface electrode 15 via a wire 17. Materials for the electrodes can be, for example, silver, titanium and the like.

The support member 13 is disposed on the outer periphery of the substrate 12. The substrate 12 is provided with terminals 16a, 16b, 16c and 16d and a heat dissipation plate 18. The terminal 16a is connected to the terminal 16c and the terminal 16b is connected to the terminal 16d via through holes formed in the substrate 12. The current generated by the solar battery cell 11 flows through the terminals 16a and 16b to the terminals 16c and 16d on the back surface of the substrate 12.

Disposing the terminals 16c and 16d on the back surface of the substrate 12 facilitates a task of connecting the concentrating solar battery 10 to the plate 20, which will be described later, and eliminates the need to horizontally extend wiring for extracting the current generated by the solar battery cell as with the case of conventional concentrating solar batteries. Accordingly, a concentrating solar battery 10 having a hermetically sealed structure can be easily configured and the width of the substrate can be reduced, whereby reduction in the size of the concentrating solar battery 10 and reduction of the area of the plate 20 can be achieved. As materials for the substrate 12, materials having both heat dissipation properties and electrical insulation properties are most suitable. In particular, ceramic materials such as aluminum nitride (AlN), silicon nitride (SiN), aluminum oxide (AlO₃) and silicon carbide (SiC) are effective.

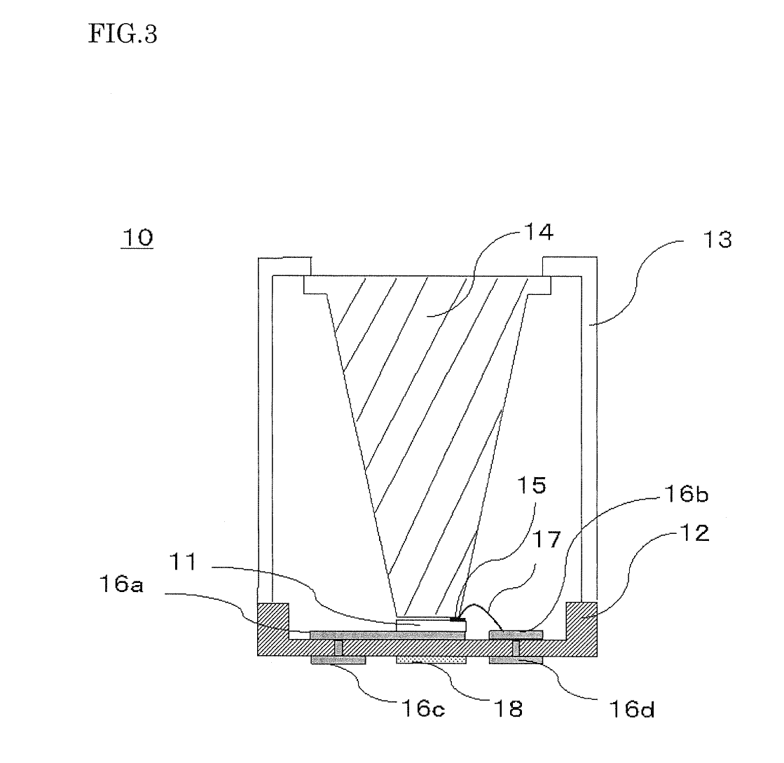

FIG. 3 shows an example of another shape of the substrate 12. As shown in FIG. 3, the substrate 12 may have a substantially U shape with its opening facing up.

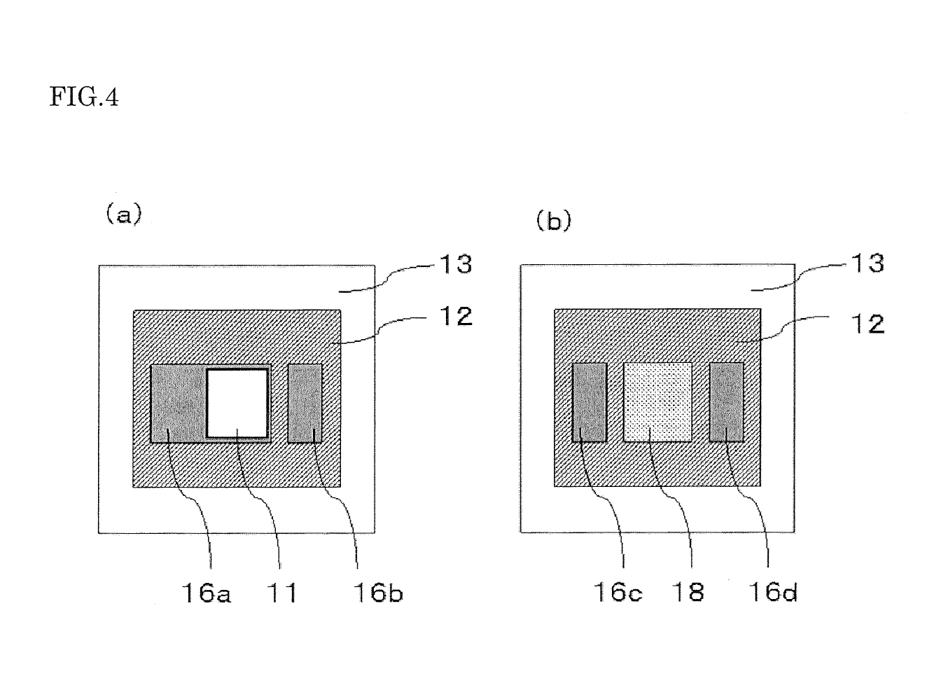

FIG. 4(a) is a plan view of the substrate 12 as viewed from above (the solar battery cell 11 mounting side), and FIG. 4(b) is a plan view of the substrate 12 as viewed from below.

The terminals 16a and 16b are formed on an upper surface of the substrate 12, and the solar battery cell 11 is bonded to the terminal 16a by soldering. As shown in FIG. 2, the surface electrode 15 of the solar battery cell 11 and the terminal 16b are connected by bonding with the wire 17. The two terminals 16c and 16d on the undersurface of the substrate 12 are respectively connected to the aforementioned terminals 16a and 16b via through holes with the substrate 12 therebetween, and connected to exposed wiring portions 21a and 21b, which will be described later, provided in the plate 20 by soldering. On the undersurface of the substrate 12, the heat dissipation plate 18 is disposed at a position that is between the terminals 16c and 16d provided on the right and left sides and is directly below the solar battery cell 11. The heat dissipation plate 18 is disposed for the purpose of suppressing temperature increase in the solar battery cell 11 caused by received sunlight, as well as dissipating heat to the outside in order to increase the power generation efficiency. As a material for the heat dissipation plate 18, in addition to copper, aluminum is also effective. The heat dissipation plate 18 is connected to an exposed heat dissipation portion 23, which will be described later, provided in the plate 20 by soldering.

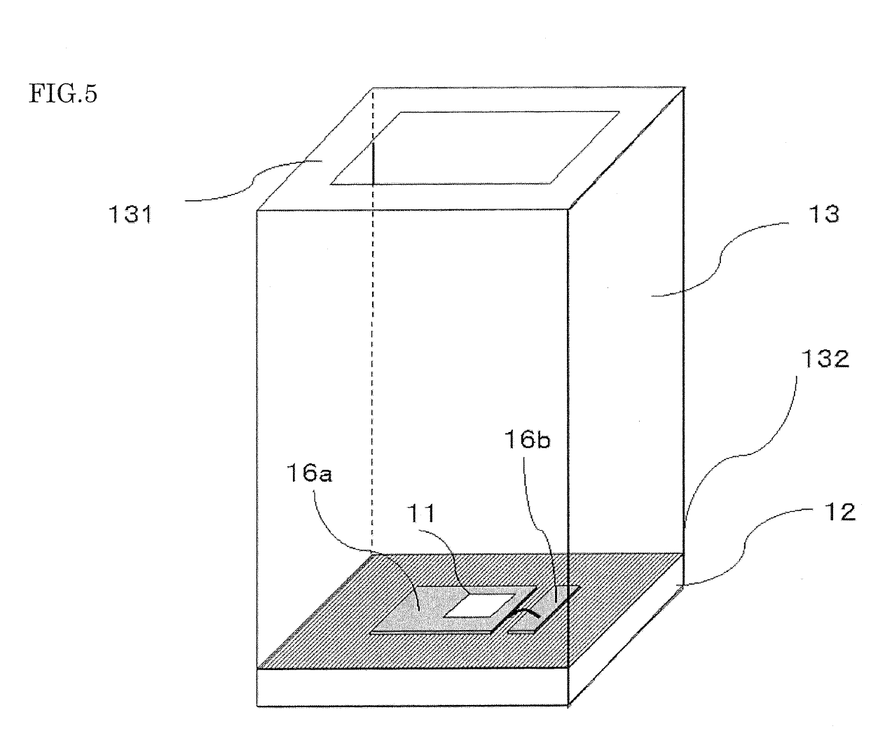

FIG. 5 is a perspective view of the concentrating solar battery 10. In this diagram, the thickness of the support member 13 is omitted, and the light guide member 14 is not illustrated for the purpose of facilitating understanding. The support member 13, which has an inverted L-shape in cross section as described above, holds the light guide member 14 with its upper rim and stands upright around the substrate 12 so as to surround the light guide member 14. The support member 13 and the substrate 12 are connected by welding or the like. Materials suitable for the support member 13 include materials that can facilitate the connecting task with respect to the substrate 12 and the light guide member 14 and reliably connect to these two members. Examples include metals having a low thermal expansion coefficient around room temperature and similar to hard glass such as Kovar, ceramic, soda-lime glass and borosilicate glass, and inexpensive and easily machinable stainless steel materials.

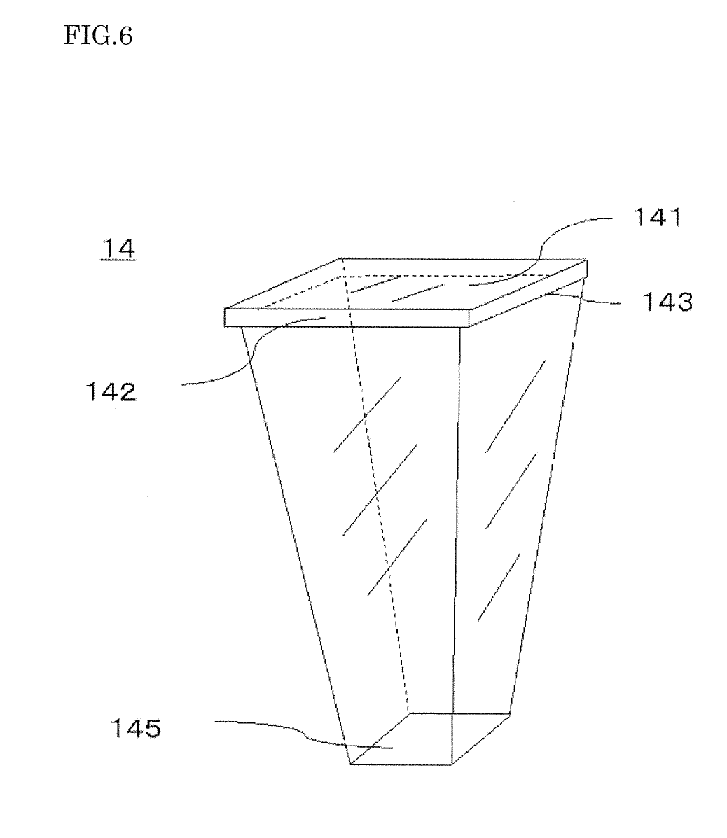

FIG. 6 is a perspective view of the light guide member 14. The light guide member 14 is disposed substantially directly above the solar battery cell 11 so as to oppose the solar battery cell 11, and has a pyramidal or conical shape whose cross section narrows from its upper surface toward its lower surface, which is on the solar battery cell 11 side. The periphery portion of an upper surface 141 has a shape slightly protruding to the outside. The protruding portion is composed of side faces 142 and an undersurface 143. Light that has entered the light guide member 14 causes the intensity distribution of optical energy in the cross-sectional area of the light guide member 14 to be uniform by repeatedly undergoing total reflection at the inside faces of the light guide member 14 while the light is traveling toward the solar battery cell 11, whereby the concentrated light is guided to the solar battery cell 11. Examples of materials for the light guide member 14 include quartz glass, Vycor glass and high alumina glass, as well as soda-lime glass, which is highly versatile, inexpensive and easily processed, and borosilicate glass, which is highly resistant to chemical erosion and thermal impact.

A procedure for assembling the concentrating solar battery 10 will be described next with reference to FIGS. 5 and 6.

First, the light guide member 14 is held in a hanging manner by the support member 13 by fixing the periphery portion of the upper surface 141 of the light guide member 14 to an upper portion 131 (the portion where the rim is inwardly protruding) of the support member 13 by glass fusion. At this time, the periphery portion of the upper surface 141 of the light guide member 14 and the upper portion 131 of the support member 13 are tightly fused without a gap therebetween.

Next, the outer periphery of the substrate 12 on which the solar battery cell 11 is placed and a lower portion 132 of the support member 13 having the light guide member 14 attached thereto are fused by a bonding method such as brazing using a metal such as silver (Ag), or soldering using an Au—Sn material.

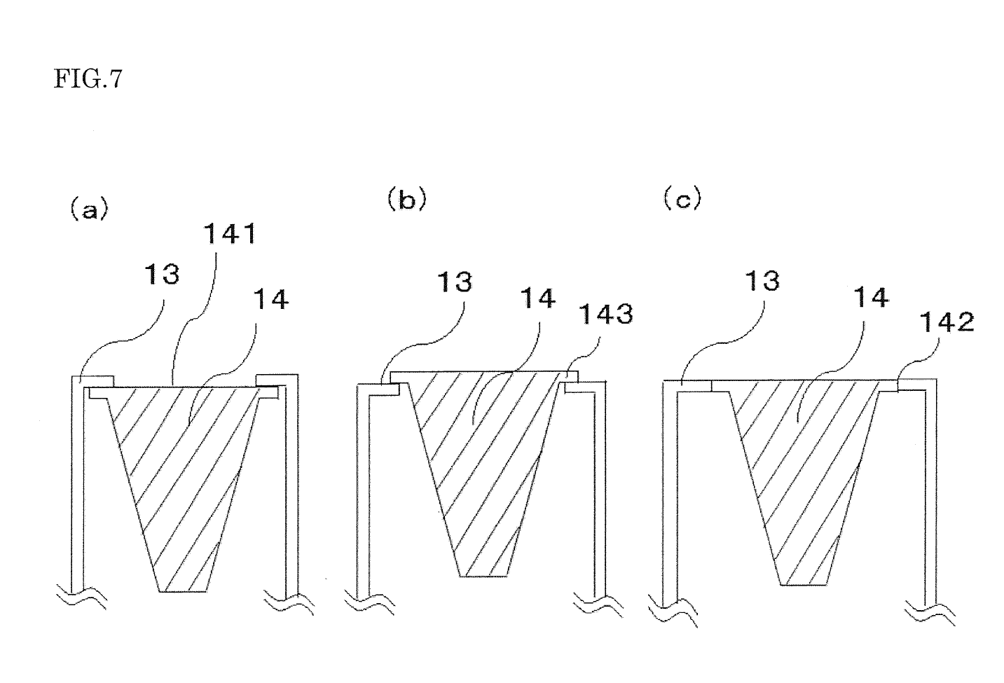

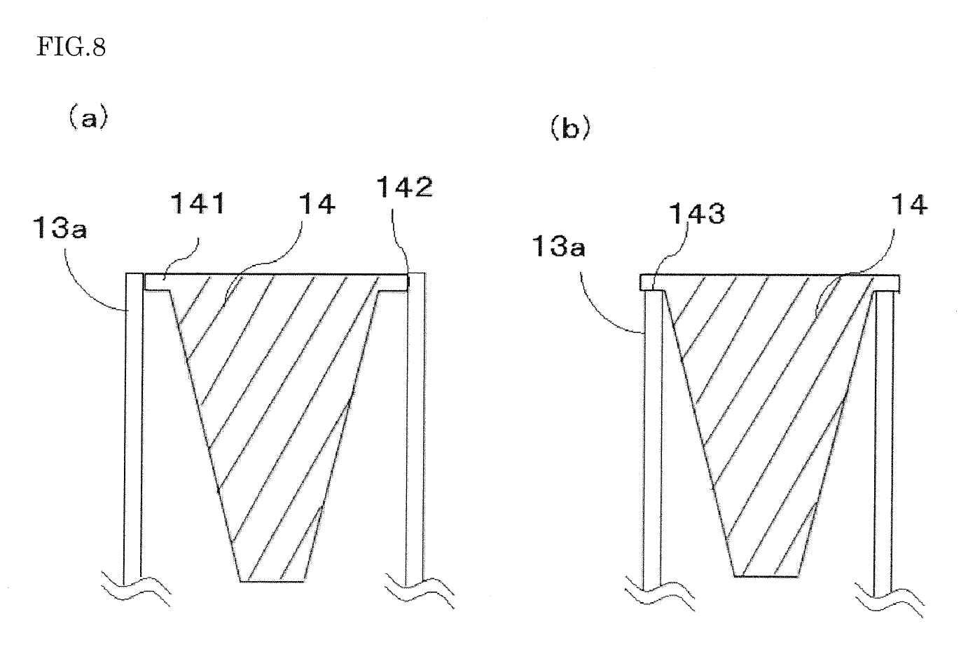

FIGS. 7 and 8 show examples of the light guide member 14 attached to the support member 13.

FIG. 7(a) shows a state in which the periphery portion of the upper surface 141 of the light guide member 14 has been attached within the support member 13 having an inverted L-shape in cross section. FIG. 7(b) shows a state in which the undersurface 143 of the periphery portion of the upper surface 141 of the light guide member 14 has been attached on top of the support member 13 having an inverted L-shape in cross section. FIG. 7(c) shows a state in which the external sides 142 of the periphery portion of the upper surface 141 of the light guide member 14 have been attached directly to the rim of the support member 13 having an inverted L-shape in cross section.

FIG. 8 shows examples of the light guide member 14 attached to a support member 13a having an I-shape in cross section. FIG. 8(a) shows a state in which the external sides 142 of the periphery portion of the upper surface 141 of the light guide member 14 have been attached to the upper inside of the support member 13a having an I-shape in cross section. FIG. 8(b) shows a state in which the underside 143 of the periphery portion of the upper surface 141 of the light guide member 14 has been attached to the upper rim face of the support member 13a having an I-shape in cross section.

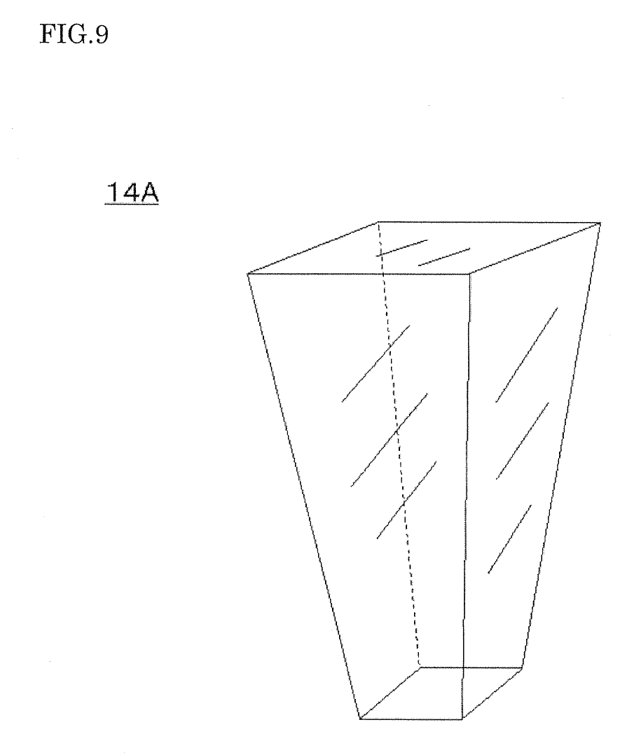

FIG. 9 is a perspective view showing another shape of the light guide member 14. The difference from FIG. 6 is that the light guide member 14 has a pyramidal shape in which the periphery portion of the upper surface 141 does not protrude to the outside. Besides the above-described shape, the light guide member 14 may have a conical shape or a shape similar thereto.

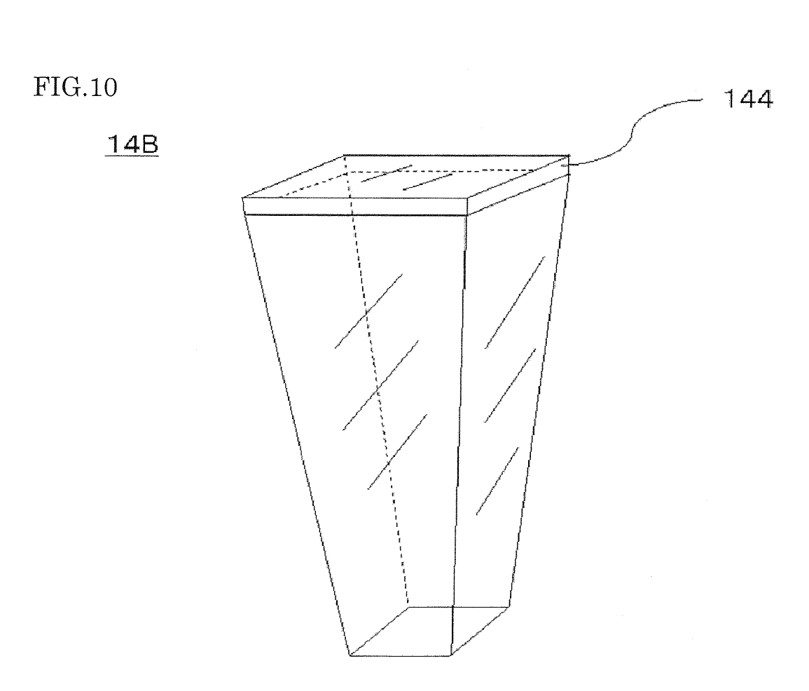

FIG. 10 is a perspective view showing yet another shape of the light guide member 14. This shape is obtained by vertically cutting off an acute corner formed by the upper surface and the side face of the pyramidal shape shown in FIG. 9. Faces 144 formed by cutting off the corners provide an advantage of easy welding when the light guide member 14 is connected to the support member 13.

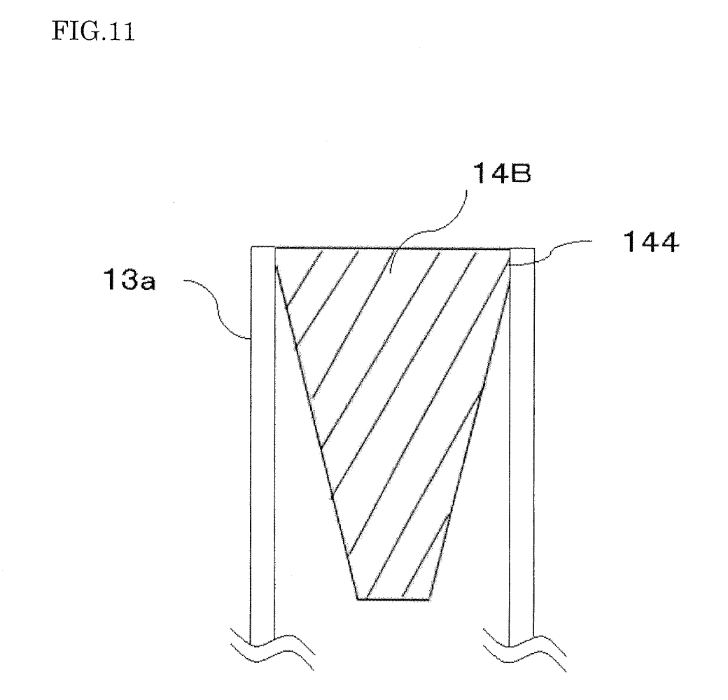

FIG. 11 shows an example in which the light guide member 14B has been attached to the support member 13a with an I-shape in cross section. The faces 144 formed by cutting off the corners of the upper surface of the light guide member 14B are attached to the upper inside of the support member 13a having an I-shape in cross section.

Other than the above methods, any attachment method can be used with various combinations of the shape of the support member 13 and the shape of the light guide member 14 as long as the support member 13 and the light guide member 14 can be tightly fused by glass fusion without a gap therebetween.

After the light guide member 14 has been attached to the support member 13 by any of the above methods, the outer periphery of the substrate 12 on which the solar battery cell 11 is placed and the lower portion 132 of the support member 13 having the light guide member 14 attached thereto are fused by a bonding method, such as brazing using a metal such as silver (Ag) or soldering using an Au—Sn material, with its inside filled with nitrogen, dry air, argon gas or the like, or with its inside depressurized.

At this time, the outer periphery of the substrate 12 and the lower portion 132 of the support member 13 are tightly fused without a gap therebetween in order to prevent the nitrogen, dry air, argon gas or the like filling the inside from leaking to the outside and the outside air from entering. Also, the undersurface 145 of the light guide member 14 is positioned so as to oppose the solar battery cell 11 and be directly above the solar battery cell 11, and then attached. Although there is a space between the solar battery cell 11 and the light guide member 14, a shorter distance between the solar battery cell 11 and the undersurface 145 of the light guide member 14 is optically advantageous.

In the assembling method described above, the light guide member 14 is first attached to the support member 13, and then the support member 13 is attached to the substrate 12. However, the procedure may be such that the support member 13 is first attached to the substrate 12 and then the light guide member 14 is attached to the support member 13, as long as the concentrating solar battery 10 is hermetically sealed by the substrate 12, the support member 13 and the light guide member 14.

The concentrating solar battery 10 produced by the above method is hermetically sealed, with the solar battery cell 11 and the light guide member 14 being surrounded by the support member 13 and the substrate 12, and with its inside filled with nitrogen, dry air, argon gas or the like or with its inside depressurized, and therefore it is independently packaged as a concentrating solar battery 10 and insulated from the outside. By configuring the concentrating solar battery 10 so as to have a hermetically sealed structure as described above, it is possible to prevent dirt, dust and the like from adhering to the light guide member 14 and affecting the light concentration efficiency, as well as preventing the light guide member 14 from being damaged or broken by an external impact.

Hermetically sealing the concentrating solar battery 10 eliminates the need for a resin sealant for protecting the solar battery cell 11 from dirt, dust, moisture and damage caused by an impact, and it is therefore possible to prevent undesirable effects such as reduction of the amount of power generation caused by problems such as deformation, discoloration and overheating of the resin.

(Configuration of Plate)

A configuration of the plate 20 will be described next.

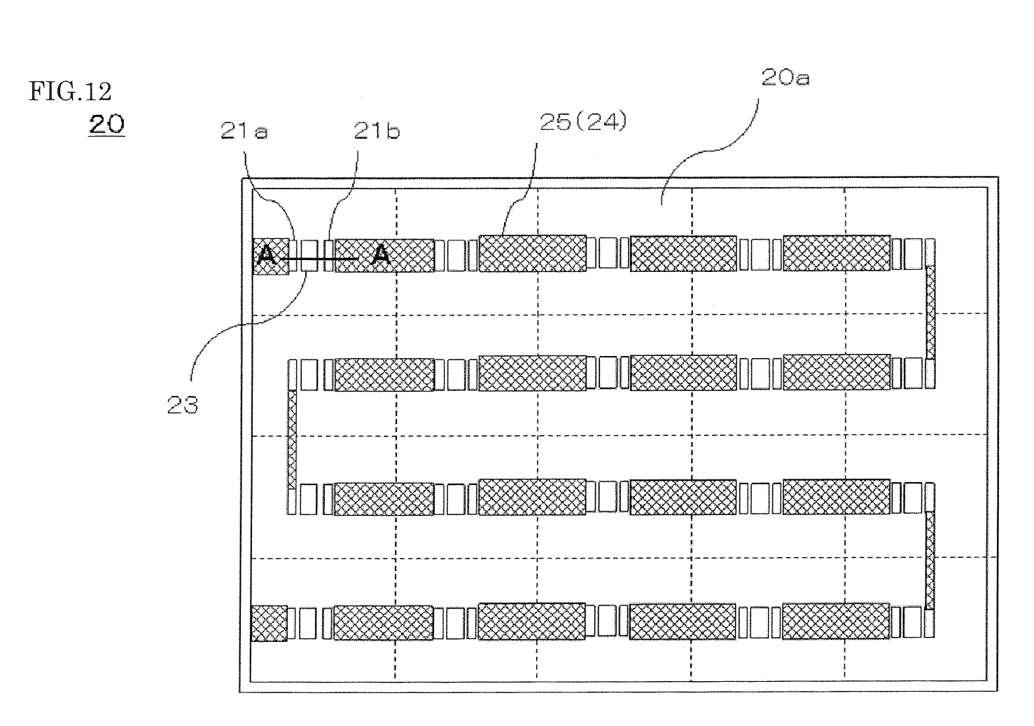

FIG. 12 is a schematic plan view of a plate 20 on which concentrating solar batteries 10 are installed, as viewed from above. A plurality of concentrating solar batteries 10 are disposed on the plate 20 made of aluminum or stainless steel. FIG. 12 shows an example of arrangement where concentrating solar batteries 10 are disposed in an array of 5 rows and 4 columns, but the arrangement is not limited thereto.

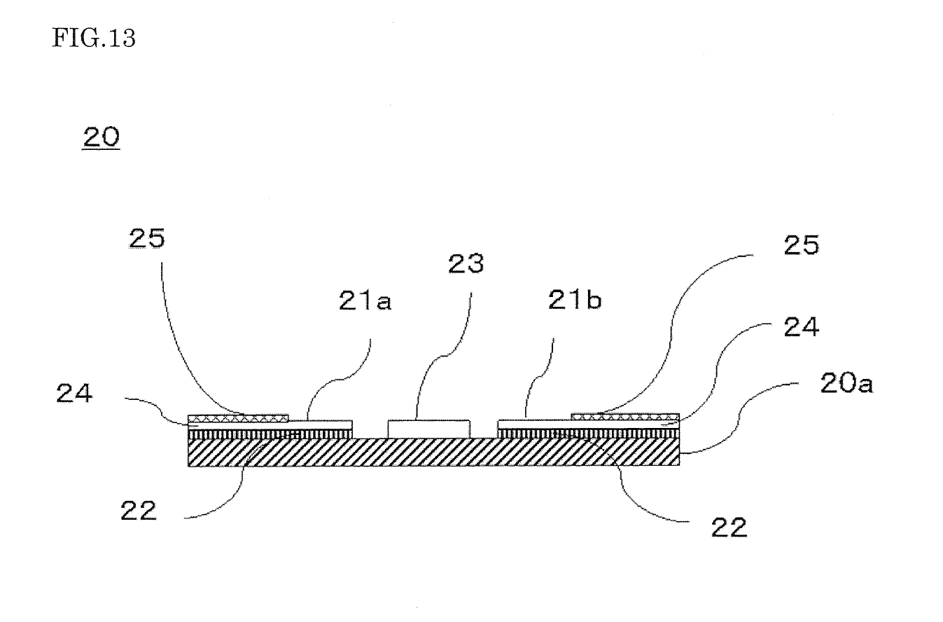

FIG. 13 is a cross-sectional view of the plate 20, taken along the line A-A shown in FIG. 12.

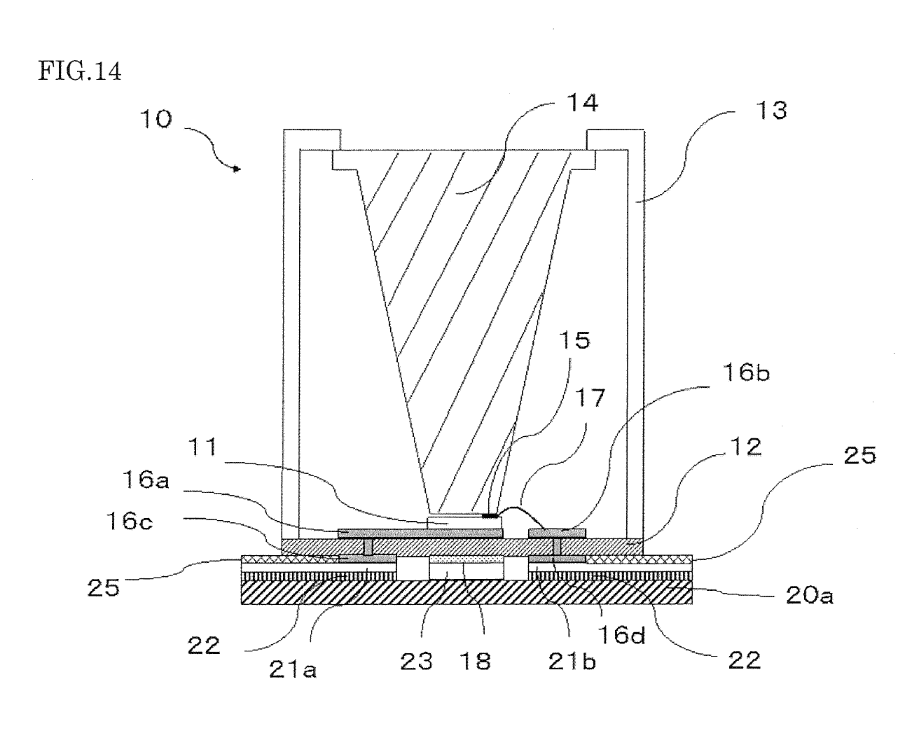

On a plate panel 20a, wiring 24 for connecting solar battery cells 11 is already formed and covered by an insulating coating film 25, and only exposed wiring portions 21a and 21b that serve as a connecting portion where a concentrating solar battery 10 is disposed are provided uncovered. In order to electrically insulate the wiring 24 and the plate panel 20a, an insulating sheet 22 is interposed between the plate panel 20a and the wiring 24. The insulating sheet 22 and the insulating coating film 25 may be the same member. When disposing a concentrating solar battery 10 on the plate 20 as shown in FIG. 14, as will be described later in detail, the exposed wiring portions 21a and 21b are respectively connected to the terminals 16c and 16d.

The exposed heat dissipation portion 23 is disposed at a position between the exposed wiring portions 21a and 21b of the plate 20. The exposed heat dissipation portion 23 is positioned directly below the solar battery cell 11 when the concentrating solar battery 10 has been attached to the plate 20. The exposed heat dissipation portion 23 is provided with a member for dissipating heat produced as a result of power generation by the solar battery cell 11 to the outside, and is connected to the heat dissipation plate 18. As a material for the exposed heat dissipation portion 23, in addition to copper, ceramic, a heat dissipation sheet or the like can be used, but copper, which has high thermal conductivity, is effective.

(Connection to Plate)

A procedure for connecting a concentrating solar battery 10 to the plate 20 will be described next.

The terminals 16c and 16d and the heat dissipation plate 18 of the concentration solar battery 10 are respectively connected to the exposed wiring portions 21a and 21b and the exposed heat dissipation portion 23 shown in FIGS. 12 and 13 by reflow soldering.

FIG. 14 is a cross-sectional view showing a state in which one concentrating solar battery 10 has been connected to the plate 20. The terminal 16c is connected to the exposed wiring portion 21a, the terminal 16d is connected to the exposed wiring portion 21b, and the heat dissipation plate 18 is connected to the exposed heat dissipation portion 23. Concentrating solar batteries 10 are sequentially connected onto the plate 20 in the manner described above.

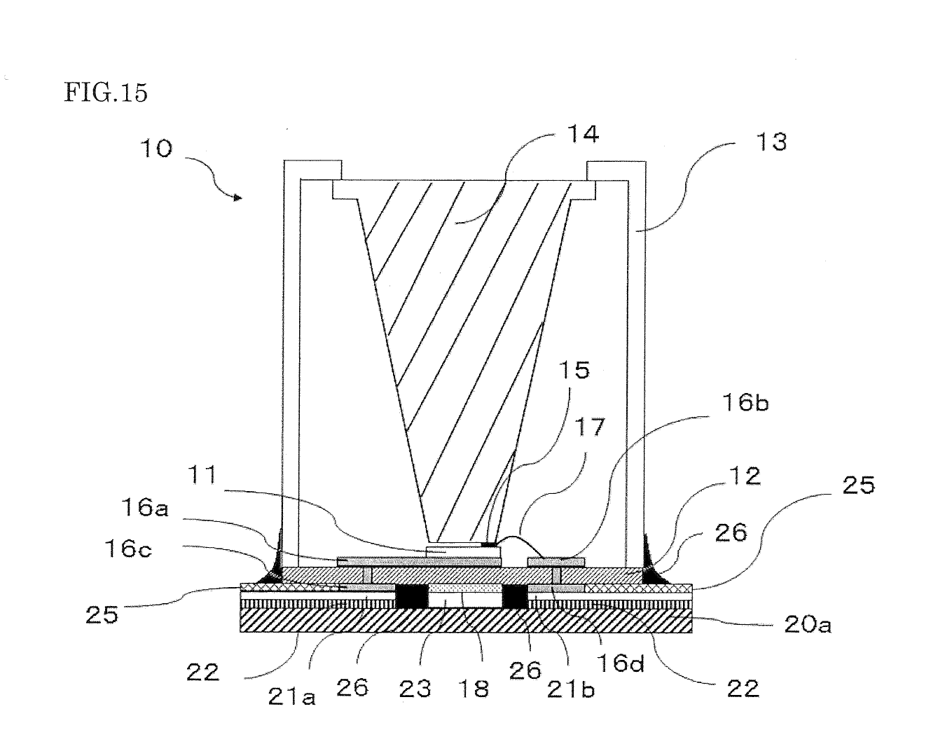

FIG. 15 is a cross-sectional view showing a state in which resin 26 has been applied around the concentrating solar battery 10 and in the space between the concentrating solar battery 10 and the connecting portion of the plate 20 after connecting the concentrating solar battery 10 to the plate 20. As the resin 26, it is suitable to use sealing resin having insulating properties and adhesion properties, and for example, silicone resin, epoxy resin or the like can be used. By applying the resin 26 around the concentrating solar battery 10 and in the space of the connecting portion, it is possible to ensure connection between the concentrating solar battery 10 and the plate 20, prevent water, dirt, dust and the like from entering from a gap, and enhance insulating properties.

As described above, the concentrating solar battery 10 of the present invention is configured as an independently packaged configuration, and therefore connection to the plate 20 is easy, and even if a fault is found in a single concentrating solar battery 10, it can be easily removed from the plate 20 and replaced by a new concentrating solar battery 10.

Furthermore, structurally, the concentrating solar battery 10 of the present invention is hermetically sealed and insulated from the outside, and therefore even without a sealant such as resin on the surface of the solar battery cell 11, it will not be damaged by dirt, dust, moisture, impact and the like, and also not be affected by deformation, discoloration, overheating caused by use of resin. It is also possible to prevent dirt, dust and the like from adhering to the periphery of the light guide member 14 and affecting the light concentration efficiency, and also prevent the lens from being damaged or broken by an external impact.

The embodiments and examples disclosed in this application are to be considered in all respects as illustrative and not limiting. The scope of the invention is indicated by the appended claims rather than by the foregoing description, and all changes which come within the meaning and range of equivalency of the claims are intended to be embraced therein.

This application claims priority based on JP 2009-299015A filed in Japan on Dec. 29, 2009. The contents thereof are herein incorporated in the present application by reference. Also, all of the documents cited in the present description are hereby specifically incorporated in the present application by reference.

### DESCRIPTION OF REFERENCE NUMERALS

1 Concentrating Solar Battery System
10 Concentrating Solar Battery
11 Solar Battery Cell
12 Substrate
13 Support Member
14 Light Guide Member
15 Surface Electrode
16a, 16b, 16c, 16d Terminal
17 Wire
18 Heat Dissipation Plate
20 Plate
21a, 21b Exposed Wiring Portion
22 Insulating Sheet
23 Exposed Heat Dissipation Portion
24 Wiring
25 Insulating Coating Film
26 Resin
30 Primary Optical Lens

1. A concentrating solar battery in which concentrated sunlight is guided to a solar battery cell, the concentrating solar battery comprising:
a substrate on which the solar battery cell is mounted;
a light guide member disposed above the solar battery cell such that a lower surface thereof opposes the solar battery cell; and
a support member that holds an upper portion of the light guide member in a hanging manner and is provided upright on the substrate,
wherein the concentrating solar battery has a structure hermetically sealed by the substrate, the light guide member and the support member.

2. The concentrating solar battery according to claim 1,
wherein the support member is configured using any one of Kovar, ceramic, soda-lime glass, borosilicate glass and stainless steel.

3. The concentrating solar battery according to claim 1,
wherein the light guide member is configured using any one of quartz glass, Vycor glass, high alumina glass, soda-lime glass and borosilicate glass.

4. The concentrating solar battery according to claim 1,
wherein the concentrating solar battery includes a terminal for extracting current generated by the solar battery cell, and the terminal has a structure that guides the current generated by the solar battery cell to an undersurface via a through hole formed in the substrate.

5. A concentrating solar battery module in which a plurality of the concentrating solar batteries according to claim 1 are disposed on a plate,
wherein a connecting portion that is connected to a solar battery cell and wiring for connecting solar battery cells are formed on the plate.

6. A concentrating solar battery system comprising the concentrating solar battery module according to claim 5 and a primary optical system that concentrates sunlight.

7. A method for manufacturing a concentrating solar battery in which concentrated sunlight is guided to a solar battery cell, the method comprising the steps of:
holding an upper portion of a light guide member in a hanging manner by a support member, placing the support member upright on a substrate on which the solar battery cell is mounted, and hermetically sealing the concentrating solar battery.

8. A method for manufacturing a solar battery module in which a plurality of concentrating solar batteries in which concentrated sunlight is guided to solar battery cells are disposed on a plate, the method comprising the steps of:
holding an upper portion of a light guide member in a hanging manner by a support member, placing the support member upright on a substrate on which a solar battery cell is mounted, and hermetically sealing the concentrating solar battery; and
connecting the concentrating solar battery to a connecting portion of the plate on which the connecting portion that is connected to the concentrating solar battery and wiring for connecting solar battery cells are formed.

9. The method for manufacturing a concentrating solar battery module according to claim 8, further comprising a step of applying resin in a space between the plate and the concentrating solar battery.
